(19) United States
(12) Patent Application Publication
(10) Pub. No.: US 2013/0085691 A1
(43) Pub. Date: Apr. 4, 2013

(54) METHOD FOR TESTING HANDHELD ELECTRONIC DEVICE

(71) Applicants: Chun-Lin HUANG, Taipei City (TW); Ching-Feng HSIEH, Taipei City (TW)

(72) Inventors: Chun-Lin HUANG, Taipei City (TW); Ching-Feng HSIEH, Taipei City (TW)

(73) Assignees: ASKEY COMPUTER CORP.; ASKEY TECHNOLOGY (JIANGSU) LTD.

(21) Appl. No.: 13/300,707

(22) Filed: Nov. 21, 2011

(30) Foreign Application Priority Data
Sep. 30, 2011 (TW) 100135588

(51) Int. Cl. G01R 31/00; G06F 19/00

(52) U.S. Cl. 702/58

(57) ABSTRACT

A method for testing a handheld electronic device installed with an open operating platform including a first testing instruction and a second testing instruction includes sending the first testing instruction to the handheld electronic device to switch the handheld electronic device from a high power consumption state to a low power consumption state; sending the second testing instruction to the handheld electronic device to switch the handheld electronic device from the low power consumption state to the high power consumption state; and executing the first testing instruction and the second testing instruction repeatedly in a loop based on a predetermined test duration and test count, such that tests performed on the handheld electronic device are precise and stable.

### CROSS-REFERENCE TO RELATED APPLICATION

This non-provisional application claims priority under 35 U.S.C. §119(a) on Patent Application No(s).100135588 filed in Taiwan, R.O.C. on Sep. 30, 2011, the entire contents of which are hereby incorporated by reference.

### FIELD OF TECHNOLOGY

The present invention relates to a method for testing a handheld electronic device, in particular to a method for testing a switch of operating states of a handheld electronic device having an open operating platform.

### BACKGROUND OF THE INVENTION

Nowadays, more and more handheld electronic device are equipped with an open operating platform. To assure the stability of the operation of the handheld electronic device, manufacturers perform related tests before the handheld electronic device is shipped out from a factory. Among these tests, the most important one is to test whether or not the open operating platform can be executed and operated in the handheld electronic device stably.

As to the wakeup and sleep functions of the open operating platform, if a user is not operating the handheld electronic device, the open operating platform executes a pause (or sleep) instruction to enter the handheld electronic device into a pause state to extend the service time of the handheld electronic device; and if a user wants to operate the handheld electronic device, the user executes an operation (or wakeup) instruction to return the open operating platform from the pause state to a wakeup state and allow the user to use the handheld electronic device.

In the prior art, a tester performs the aforementioned functional test repeatedly according to a standard operation with standard test time and test count to assure that the handheld electronic device equipped with the open operating platform can execute the wakeup and sleep functions stably.

However, a normal operation is determined by a test performed by a tester. The tester may execute an operation instruction before the execution of the pause instruction is completed, and the tester may fail to determine whether or not the handheld electronic device has actually returned from the pause state to the operation state, thus resulting in a misjudgment.

Therefore, the present invention provides a feasible testing method to overcome the problems of the conventional testing method.

### SUMMARY

It is a primary objective of the present invention to provide a method for testing a handheld electronic device, wherein the stability of the handheld electronic device equipped with an open operating platform is tested.

To achieve the aforementioned and other objectives, the present invention provides a method for testing a handheld electronic device, and the method is applied to the handheld electronic device installed with an open operating platform, a first testing instruction and second testing instruction, and comprises the steps of: (a) sending the first testing instruction to the handheld electronic device to switch the handheld electronic device from a high power consumption state to a low power consumption state; (b) sending the second testing instruction to the handheld electronic device to switch the handheld electronic device from the low power consumption state back to the high power consumption state after a predetermined wait time; (c) executing the steps (a) and (b) repeatedly in a loop based on a predetermined test count, and generating a test result after the steps (a) and (b) are completed; and (d) outputting the test result.

Compared with the prior art, the method for testing a handheld electronic device of the present invention includes an open operating platform (such as the Android operating platform), a first testing instruction and a second testing instruction installed on the handheld electronic device and, and the first testing instruction is sent and then the second testing instruction is sent after a predetermined wait time for recording a test result of the switch between a high power consumption state and a low power consumption state within a predetermined test count to output the test result after the predetermined test count is reached.

In addition, the present invention further generates an erroneous result provided for a user's determination if the handheld electronic device fails to switch from the high power consumption state to the low power consumption state or from the low power consumption state back to the high power consumption state.

### BRIEF DESCRIPTION OF THE DRAWINGS

FIG. 1 is a flow chart of a method for testing a handheld electronic device in accordance with a first preferred embodiment of the present invention; and

FIG. 2 is a flow chart of a method for testing a handheld electronic device in accordance with a second preferred embodiment of the present invention.

### DETAILED DESCRIPTION

The objects, characteristics and effects of the present invention will become apparent with the detailed description of the preferred embodiments and the illustration of related drawings as follows.

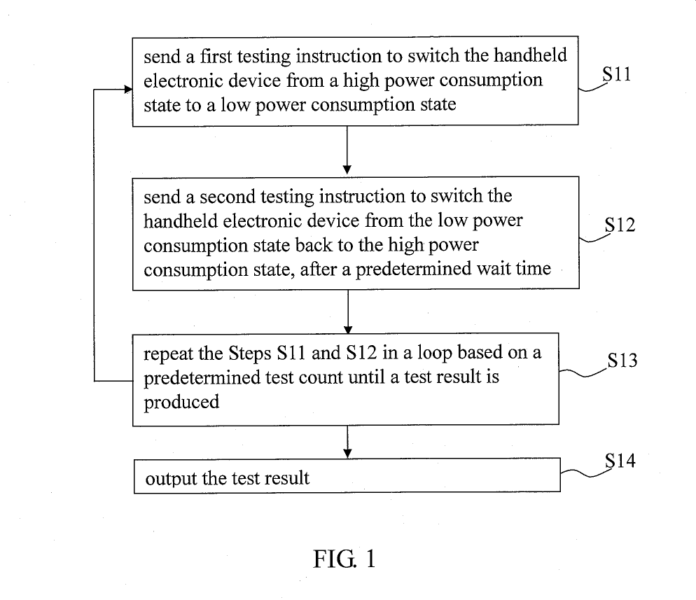

With reference to FIG. 1 for a flow chart of a method for testing a handheld electronic device in accordance with the first preferred embodiment of the present invention, the method for testing the handheld electronic device is provided for testing a handheld electronic device equipped with an open operating platform, and the open operating platform includes a first testing instruction and a second testing instruction, and the open operating platform can be an Android operating platform.

Wherein, the testing method starts at Step S11. S11: Send a first testing instruction to switch the handheld electronic device from a high power consumption state to a low power consumption state. In a preferred embodiment, the high power consumption state refers to an operating state (or wakeup state) of the handheld electronic device, and the low power consumption state refers to a pause state (or sleep state) of the handheld electronic device. In other words, the first testing instruction is executed to switch the handheld electronic device from the operating state to the pause state.

S12: Send a second testing instruction to switch the handheld electronic device from the low power consumption state back to the high power consumption state, after a predetermined wait time. In a preferred embodiment, the predetermined wait time falls within a range of 2˜3 seconds.

In other words, the handheld electronic device is situated at the low power consumption state after the step S 11 takes place, and then the second testing instruction is executed to switch the handheld electronic device from the low power consumption state back to the high power consumption state, which is from the sleep state back to the operation state, after the predetermined wait time.

S13: Repeat the Steps S11 and S12 in a loop based on a predetermined test count until a test result is produced. In a preferred embodiment, the predetermined test count falls within a range of 4900 to 5100 times.

In addition, the aforementioned test result shows that the handheld electronic device can be switched from the high power consumption state to the low power consumption state as well as from the low power consumption state back to the high power consumption state for a normal operation.

In a preferred embodiment, an incrementing or decrementing method can be used to determine whether or not the predetermined test count is reached and such method is used as a basis for counting. For example, the count is decremented by 1 for each time of testing until the predetermined test count reaches 0 or a negative value; or the count is incremented by 1 for each time of testing until the test count reaches the predetermined test count.

S14: Output the test result. The outputted test results are provided for users to analyze the count of the handheld electronic device that is switched from the high power consumption state to the low power consumption state and from the low power consumption state back to the high power consumption state normally.

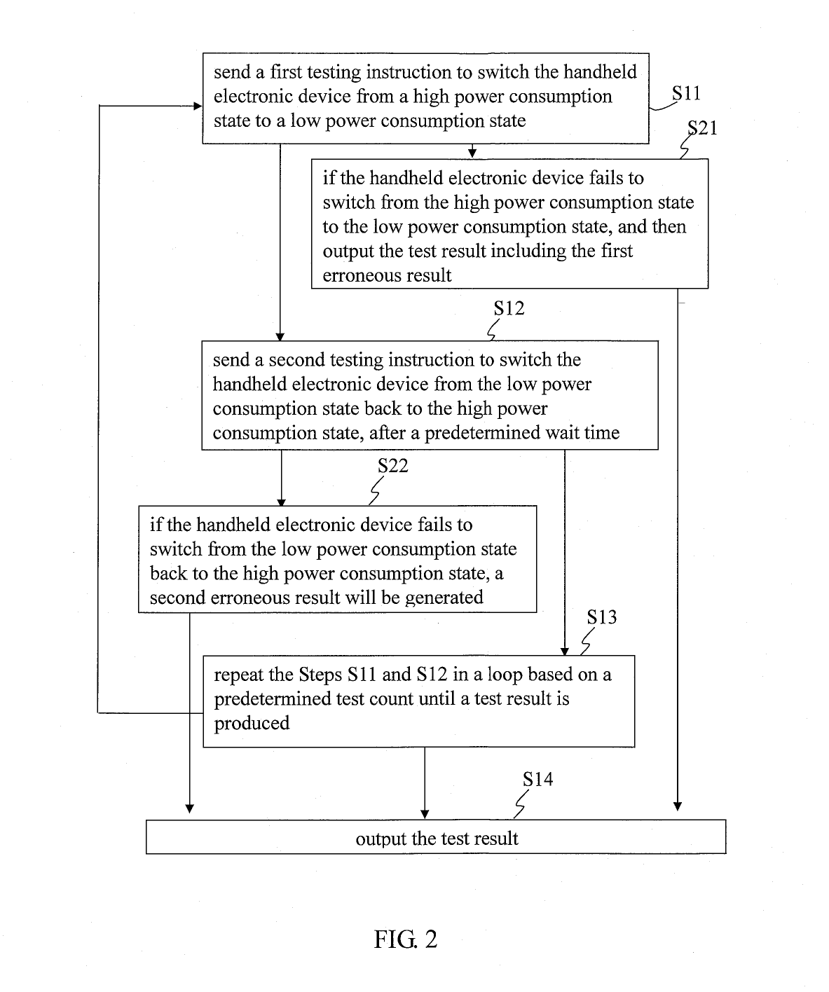

With reference to FIG. 2 for a flow chart of a method for testing a handheld electronic device in accordance with the second preferred embodiment of the present invention, the second preferred embodiment comprises the same steps of the first preferred embodiment and further comprises the following steps. After the step S11 takes place, the step S21 is performed to generate a first erroneous result and interrupt the steps (b) and (c) if the handheld electronic device fails to switch from the high power consumption state to the low power consumption state, and then output the test result including the first erroneous result in the step (d). In other words, if the handheld electronic device fails to switch from the high power consumption state to the low power consumption state, such situation is recorded as the first erroneous result and the test result including the first erroneous result is outputted to let users know about the situation that the handheld electronic device fails to switch from the high power consumption state to the low power consumption state.

In addition, the method further comprises the step S22 after the step S12 takes place. In the step S22, if the handheld electronic device fails to switch from the low power consumption state back to the high power consumption state, a second erroneous result will be generated and the Step (c) will be interrupted. In Step (d), the test result including the second erroneous result is outputted. In other words, if the handheld electronic device fails to switch from the low power consumption state back to the high power consumption state, such situation will be recorded as the second erroneous result, and the test result including the second erroneous result is outputted to let users know about the situation that the handheld electronic device fails to switch from the low power consumption state back to the high power consumption state.

While the invention has been described by means of specific embodiments, numerous modifications and variations could be made thereto by those skilled in the art without departing from the scope and spirit of the invention set forth in the claims.

What is claimed is:

1. A method for testing a handheld electronic device, applied to the handheld electronic device installed with an open operating platform, a first testing instruction and second testing instruction, comprising the steps of:
(a) sending the first testing instruction to the handheld electronic device to switch the handheld electronic device from a high power consumption state to a low power consumption state;
(b) sending the second testing instruction to the handheld electronic device to switch the handheld electronic device from the low power consumption state back to the high power consumption state, after a predetermined wait time;
(c) executing the steps (a) and (b) repeatedly in a loop based on a predetermined test count, and generating a test result after the steps (a) and (b) are completed; and
(d) outputting the test result.

2. The method for testing a handheld electronic device as recited in claim 1, wherein the low power consumption state is a pause/sleep state of the handheld electronic device, and the high power consumption state is an operating/wakeup state of the handheld electronic device.

3. The method for testing a handheld electronic device as recited in claim 2, wherein the step (a) further comprises the steps of generating a first erroneous result and interrupting the steps (b) and (c), and output the test result including the first erroneous result in the step (d), if the handheld electronic device fails to switch from the high power consumption state to the low power consumption state.

4. The method for testing a handheld electronic device as recited in claim 2, wherein the step (b) further comprises the steps of generating a second erroneous result and interrupting the step (c) and outputting the test result including the second erroneous result in the step (d) if the handheld electronic device fails to switch from the low power consumption state back to the high power consumption state.

5. The method for testing a handheld electronic device as recited in claim 2, wherein the predetermined wait time falls within a range of 2˜3 seconds.

6. The method for testing a handheld electronic device as recited in claim 5, wherein the predetermined test count falls within a range of 4900˜5100 times.

7. The method for testing a handheld electronic device as recited in claim 6, wherein the open operating platform is an Android operating platform.
